(19) United States
(12) Patent Application Publication
(10) Pub. No.: US 2025/0280704 A1
(43) Pub. Date: Sep. 4, 2025

(54) DISPLAY DEVICE

(71) Applicant: LG Display Co., Ltd., Seoul (KR)

(72) Inventors: Jaehyuk LEE, Paju-si (KR); KyoungJin PARK, Paju-si (KR)

(73) Assignee: LG Display Co., Ltd., Seoul (KR)

(21) Appl. No.: 18/792,848

(22) Filed: Aug. 2, 2024

(30) Foreign Application Priority Data
Feb. 29, 2024 (KR) 10-2024-0029843

(51) Int. Cl. H10K 59/80; H10K 59/122; H10K 59/124; H10K 59/131; H10K 59/38

(52) U.S. Cl. CPC H10K 59/873; H10K 59/122; H10K 59/124; H10K 59/131; H10K 59/38

(57) ABSTRACT

A display device may include: a substrate; a plurality of pixels, each of the plurality of pixels including an emission area and a transmission area; a first structure disposed in the transmission area on the substrate and having an undercut shape; an encapsulation substrate disposed on the substrate; and a second structure disposed between the substrate and the encapsulation substrate so as to cover the first structure. In one or more aspects, it is possible to improve reliability by suppressing the permeation of foreign matter, such as moisture, gas, or oxygen, from the outside into the display device.

### CROSS-REFERENCE TO RELATED APPLICATIONS

This application claims the benefit of and priority to Korean Patent Application No. 10-2024-0029843 filed on Feb. 29, 2024, in the Korean Intellectual Property Office, the entire disclosure of which is incorporated herein by reference for all purposes.

### BACKGROUND

### Technical Field

The present disclosure relates to a display device, and more particularly, for example, without limitation, to a display device with improved reliability.

### Description of the Related Art

As it enters the information era, a field of a display device which visually expresses electrical information signals has been rapidly developed. Also, studies are continued to improve performances of various display devices, such as reduced thickness, light weight, and low power consumption.

Representative display devices may include a liquid crystal display device (LCD), a field emission display device (FED), an electro-wetting display device (EWD), an organic light emitting display device (OLED), a LED display device, a micro-LED display device and the like.

An electroluminescent display device represented by an organic light emitting display device and a LED display device is a self-emitting display device and does not need a separate light source unlike a liquid crystal display device. Thus, the electroluminescent display device can be manufactured to be light and thin. Further, the electroluminescent display device has advantages in terms of power consumption due to low voltage driving, and is excellent in terms of color implementation, a response speed, a viewing angle, and a contrast ratio (CR). Therefore, electroluminescent display devices are expected to be utilized in various fields.

The description of the related art should not be assumed to be prior art merely because it is mentioned in or associated with this section. The description of the related art includes information that describes one or more aspects of the subject technology, and the description in this section does not limit the invention.

### SUMMARY

One or more aspects of the present disclosure are directed to providing a display device whose reliability is improved by suppressing the permeation of foreign matter, such as moisture, gas, or oxygen, from the outside into the display device.

One or more other aspects of the present disclosure are directed to providing a display device which can suppress a dark spot by pressing (hereinafter, referred to as “pressing dark spot”) caused by foreign matter generated inside the display device by maintaining a cell gap during a process of bonding a substrate to an encapsulation substrate.

Aspects of the present disclosure are not limited to the above-mentioned aspects, and other aspects, which are not mentioned above, can be clearly understood by those skilled in the art from the following descriptions.

A display device according to an exemplary embodiment of the present disclosure includes a substrate, a plurality of pixels, each of the plurality of pixels including an emission area and a transmission area, a first structure disposed in the transmission area on the substrate and having an undercut shape, an encapsulation substrate disposed on the substrate, and a second structure disposed between the substrate and the encapsulation substrate so as to cover the first structure.

Other detailed matters of the exemplary embodiments are included in the detailed description and the drawings.

According to an exemplary embodiment of the present disclosure, a display device includes a second structure which is disposed to cover a first structure disposed in a transmission area and having an undercut shape. Thus, it is possible to improve the reliability of the display device by suppressing the permeation of foreign matter, such as moisture, gas, or oxygen, from the outside into the display device.

According to an exemplary embodiment of the present disclosure, the second structure of the display device is disposed in the transmission area. Thus, a uniform cell gap can be maintained by the second structure during a process of bonding a substrate to an encapsulation substrate. Therefore, it is possible to suppress a pressing dark spot caused by foreign matter generated inside the display device.

The effects according to one or more aspects of the present disclosure are not limited to the contents exemplified above, and more various effects are included in the present specification.

The objects to be achieved by one or more aspects of the present disclosure, the means for achieving the objects, and the effects of one or more aspects of the present disclosure described above do not specify essential features of the claims, and, thus, the scope of the claims is not limited to the disclosure of the present disclosure.

Other aspects, effects, objects, devices, methods, features and advantages will be, or will become, apparent to one with skill in the art upon examination of the drawings and detailed description herein. It is intended that all such aspects, effects, objects, devices, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a block diagram for explaining a display device according to an exemplary embodiment of the present disclosure;

FIG. 2 is a schematic circuit diagram of a sub-pixel according to an exemplary embodiment of the present disclosure;

FIG. 3 is a detailed circuit diagram of the sub-pixel according to an exemplary embodiment of the present disclosure;

FIG. 4A is a schematic plan view of a pixel area on a substrate of the display device according to an exemplary embodiment of the present disclosure;

FIG. 4B is a schematic plan view of the pixel area on an encapsulation substrate of the display device according to an exemplary embodiment of the present disclosure;

FIG. 5 is an example of a cross-sectional view taken along a line V-V′ of FIG. 4A;

FIGS. 6A to 6F are schematic diagrams illustrating a method of manufacturing a display device according to an exemplary embodiment of the present disclosure;

FIG. 7 is a cross-sectional view of a display device according to another exemplary embodiment of the present disclosure; and

FIG. 8 is a cross-sectional view of a display device according to yet another exemplary embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

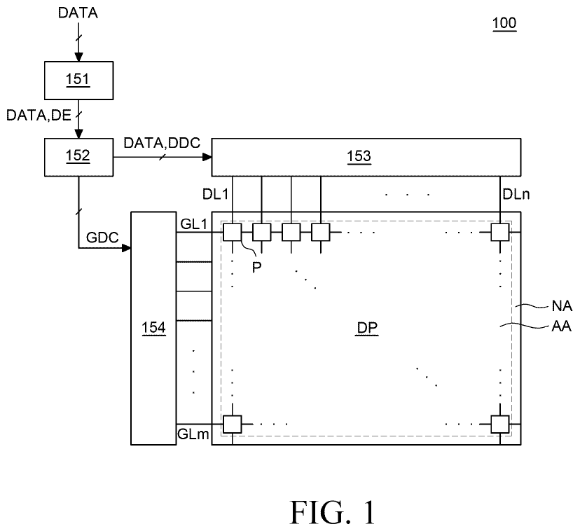

FIG. 1 is a block diagram for explaining a display device according to an exemplary embodiment of the present disclosure.

Referring to FIG. 1, the display device according to an exemplary embodiment of the present disclosure may include an image processor 151, a timing controller 152, a data driver 153, a scan driver 154, and a display panel DP, without being limited thereto. As an example, at least one of the above-mentioned components may be omitted, and/or one or more additional component may be further included.

The image processor 151 may output a data enable signal DE together with a data signal DATA supplied, for example, from the outside.

Further, for example, the image processor 151 may output one or more of a vertical synchronization signal, a horizontal synchronization signal, and a clock signal in addition to the data enable signal DE.

The timing controller 152 may receive the data enable signal DE or the data signal DATA, together with driving signals including the vertical synchronization signal, the horizontal synchronization signal, the clock signal, etc., from the image processor 151. The timing controller 152 may output a gate timing control signal GDC for controlling operation timing of the scan driver 154 and a data timing control signal DDC for controlling operation timing of the data driver 153 based on the driving signals.

The data driver 153 may sample and latch the data signal DATA received from the timing controller 152 in response to the data timing control signal DDC received from the timing controller 152. Also, the data driver 153 may convert the sampled and latched data signal DATA into a gamma reference voltage. The data driver 153 may output the converted data signal DATA through data lines DL1 to DLn. The data driver 153 may be configured in the form of an integrated circuit (IC) or may be mounted on the display panel DP, without being limited thereto. As an example, the data driver 153 may be separately provided (for example, on a separate panel), and then connected to the display panel DP in a tape automated bonding (TAB) method, a chip on glass (COG) method, a chip on panel (COP) method, or a chip on film (COF) method, without being limited thereto.

Also, the scan driver 154 may output a scan signal in response to the gate timing control signal GDC received from the timing controller 152. The scan driver 154 may output the scan signal through gate lines GL1 to GLm. The scan driver 154 may be configured in the form of an integrated circuit (IC) or may be mounted on the display panel DP in a gate-in-panel (GIP) manner. As an example, the scan driver 154 may be separately provided (for example, on a separate panel), and then connected to the display panel DP in a tape automated bonding (TAB) method, a chip on glass (COG) method, a chip on panel (COP) method, or a chip on film (COF) method, without being limited thereto.

The display panel DP may display an image in response to the converted data signal DATA and the scan signal respectively received from the data driver 153 and the scan driver 154.

The display panel DP may include a display area AA and a non-display area NA adjacent to (e.g., partially or fully enclosing) the display area AA.

The display area AA is an area of the display device 100 in which images are displayed. The display area AA may include a plurality of sub-pixels constituting a plurality of pixels P, and a circuit for driving the plurality of sub-pixels. The plurality of sub-pixels may be minimum units constituting the display area AA, and n number of sub-pixels may constitute a pixel P. As an example, n may be natural number equal to or greater than 1 or 2. For example, the sub-pixels may include a red sub-pixel, a green sub-pixel, and a blue sub-pixel, or may include a white sub-pixel, a red sub-pixel, a green sub-pixel, and a blue sub-pixel, without being limited thereto. As an example, a sub-pixel of other colors may be alternatively or additionally included. Further, as an example, the sub-pixels may have one or more different emission areas depending on emission characteristics, without being limited thereto. As an example, at least some of the sub-pixels may have the same emission area.

A plurality of lines for transmitting various signals to the plurality of pixels P is disposed in the display area AA. For example, the plurality of lines may include a plurality of data lines DL1 to DLn for supplying a data voltage to the plurality of pixels P, respectively. Also, the plurality of lines may include a plurality of gate lines GL1 to GLm for supplying a scan signal to the plurality of pixels P, respectively. The plurality of gate lines GL1 to GLm may extend in one direction in the display area AA and may be connected to the plurality of pixels P. The plurality of data lines DL1 to DLn may extend in a different direction from the one direction (e.g., a direction perpendicular to the one direction, without being limited thereto) in the display area AA and may be connected to the plurality of pixels P. Besides, a low-potential power line, a high-potential power line, etc. may be further disposed in the display area AA. However, the present disclosure is not limited thereto.

The non-display area NA is an area in which no image is displayed, and may be defined as an area extending from the display area AA. A link line or a pad electrode for transmitting a signal to the plurality of pixels P in the display area AA, or various driver ICs, such as a gate driver IC and a data driver IC, may be disposed in the non-display area NA.

As an example, the non-display area NA may be not bent (e.g., flat). As an example, the non-display area NA may be bent toward the rear surface of the display panel DP. As an example, the non-display area NA may be bent so that at least a portion of the non-display area NA cannot be seen from the front. As an example, at least a portion of the non-display area NA may be covered by a case (not shown). The non-display area NA is also referred to as a bezel area.

FIG. 1 illustrates that the non-display area NA encloses the display area AA having a quadrangular shape. However, the shape and disposition of the display area AA and the non-display area NA are not limited to the example illustrated in FIG. 1. That is, the display area AA and the non-display area NA may be suitable for the design of an electronic device equipped with the display device 100. As an example, the display area AA may have various shape such as an oval shape, a circular shape, a polygonal shape, etc., other than the quadrangular shape.

The display device 100 may further include various additional components configured to generate various signals or drive the plurality of pixels P in the display area AA. The additional components for driving the plurality of pixels P may include an inverter circuit, a multiplexer, an electrostatic discharge (ESD) circuit, etc. The display device 100 may also include additional components related to functions other than the function of driving the plurality of pixels P. For example, the display device 100 may further include additional components for providing a touch sensing function, a user authentication function (e.g., fingerprint recognition), a multi-level pressure sensing function, a tactile feedback function, etc. The additional components may be located in an external circuit connected to the non-display area NA and/or a connection interface, without being limited thereto.

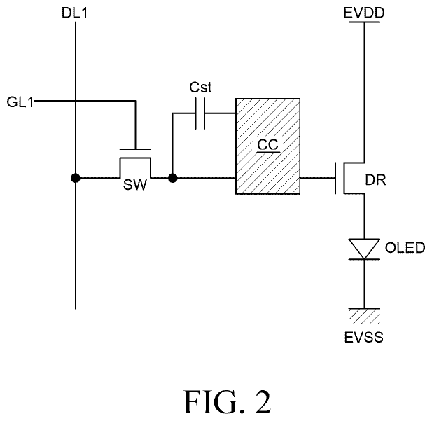

FIG. 2 is a schematic circuit diagram of a sub-pixel according to an exemplary embodiment of the present disclosure.

Referring to FIG. 2, each sub-pixel may include a switching transistor SW, a driving transistor DR, a capacitor Cst, a compensation circuit CC, and an organic light emitting diode OLED. Although the illustration and the description are mainly made by focusing on an organic light emitting diode OLED, the present application is not limited thereto. As an example, the illustration and the description may be similarly applied to a LED or a micro-LED, etc.

For example, the switching transistor SW may perform a switching operation so that a data signal supplied through a first data line DL1 is stored in the capacitor Cst as a data voltage in response to a scan signal supplied through a first gate line GL1. Further, for example, the driving transistor DR enables a driving current to flow between a first power line EVDD (high-potential voltage) and a second power line EVSS (low-potential voltage) based on the data voltage stored in the capacitor Cst. Also, the organic light emitting diode OLED may emit light depending on the driving current generated by the driving transistor DR.

The compensation circuit CC is a circuit added to the sub-pixel and compensates for a threshold voltage of the driving transistor DR. The compensation circuit CC may be composed of one or more transistors. A configuration of the compensation circuit CC may be variously changed depending on an external compensation method and will be described below.

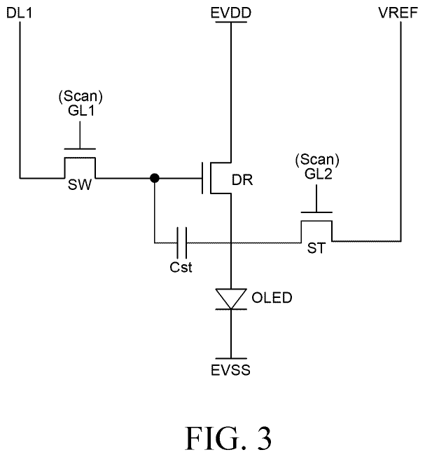

FIG. 3 is a detailed circuit diagram of the sub-pixel according to an exemplary embodiment of the present disclosure.

Referring to FIG. 3, the compensation circuit CC may include, for example, a sensing transistor ST and a sensing line (or a reference line) VREF.

Herein, the sensing transistor ST may be connected between a drain electrode of the driving transistor DR and a first electrode of the organic light emitting diode OLED (hereinafter, referred to as “sensing node”). The sensing transistor ST may operate to supply an initialization voltage (or sensing voltage) transferred through the sensing line VREF to the sensing node of the driving transistor DR. Also, the sensing transistor ST may operate to sense a voltage or current of the sensing node of the driving transistor DR or the sensing line VREF.

A source electrode or drain electrode of the switching transistor SW may be connected to the first data line DL1. The other one of the source electrode and the drain electrode of the switching transistor SW may be connected to a gate electrode of the driving transistor DR.

A source electrode or drain electrode of the driving transistor DR may be connected to the first power line EVDD. The other one of the source electrode and the drain electrode of the driving transistor DR may be connected to the first electrode, which is the anode, of the organic light emitting diode OLED.

Further, one electrode (e.g., a lower electrode) of the capacitor Cst may be connected to the gate electrode of the driving transistor DR, and the other electrode (e.g., an upper electrode) of the capacitor Cst may be connected to the first electrode, which is an anode, of the organic light emitting diode OLED. The first electrode of the organic light emitting diode OLED may be connected to the other one of the source electrode and the drain electrode of the driving transistor DR. Also, a second electrode, which is a cathode, of the organic light emitting diode OLED may be connected to the second power line EVSS.

A source electrode or drain electrode of the sensing transistor ST may be connected to the sensing line VREF. The other one of the source electrode and the drain electrode of the sensing transistor ST may be connected to the first electrode of the organic light emitting diode OLED, which is the sensing node, and the other one of the source electrode and the drain electrode of the driving transistor DR.

An operation time of the sensing transistor ST may be similar/identical to or different from that of the switching transistor SW depending on an external compensation algorithm (or the configuration of the compensation circuit). For example, a gate electrode of the switching transistor SW may be connected to the first gate line GL1, and a gate electrode of the sensing transistor ST may be connected to a second gate line GL2. Herein, a scan signal Scan may be transmitted to the first gate line GL1 and a sensing signal Sense may be transmitted to the second gate line GL2. As another example, the first gate line GL1 connected to the gate electrode of the switching transistor SW and the second gate line GL2 connected to the gate electrode of the sensing transistor ST may be connected so that they can be commonly shared.

As an example, the sensing line VREF may be connected to the data driver. In this case, the data driver may sense the sensing node of the sub-pixel and generate a sensing result in real time or during a non-display period of an image, or during a period of N frames (N is an integer equal to or greater than 1).

As an example, the switching transistor SW and the sensing transistor ST may be turned on at the same time. In this case, a sensing operation through the sensing line VREF and a data output operation for outputting the data signal are separated (or distinguished) from each other in a time division manner of the data driver.

Besides, a digital data signal, an analog data signal, a gamma signal, or the like may be compensated according to the sensing result. The compensation circuit for generating a compensation signal (or a compensation voltage) based on the sensing result may be implemented inside the data driver, inside the timing controller, or inside a separate circuit.

As described above, FIG. 3 illustrates, for example, the sub-pixel having a 3T (Transistor) 1C (Capacitor) structure including the switching transistor SW, the driving transistor DR, the capacitor Cst, the organic light emitting diode OLED, and the sensing transistor ST. However, one or more transistors or capacitors may be further included. As an example, when the compensation circuit CC is added to the sub-pixel, the sub-pixel may have various structures, such as 3T2C, 4T2C, 5T1C, and 6T2C.

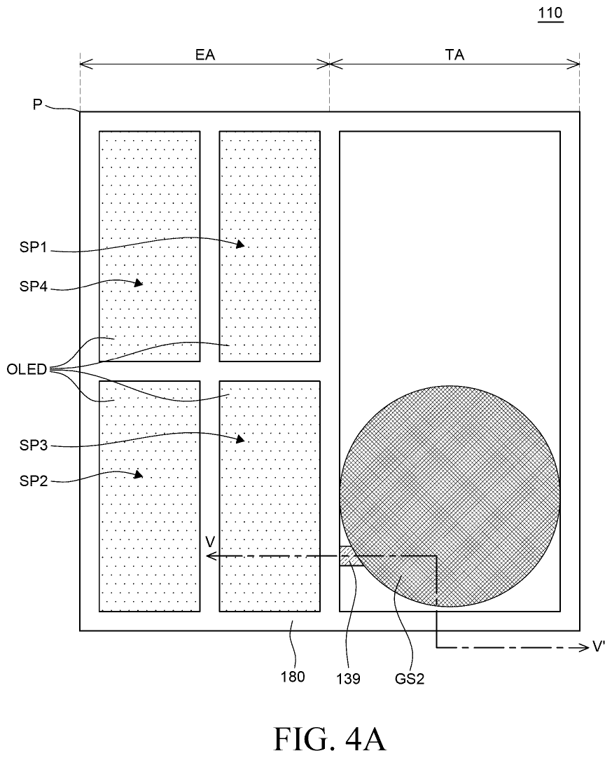

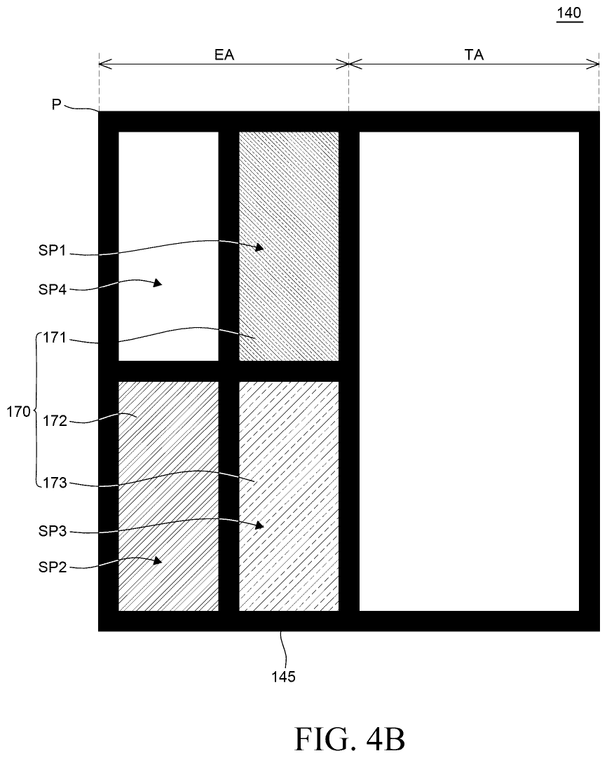

FIG. 4A is a schematic plan view of a pixel area on a substrate of the display device according to an exemplary embodiment of the present disclosure. FIG. 4B is a schematic plan view of the pixel area on an encapsulation substrate of the display device 100 according to an exemplary embodiment of the present disclosure.

Referring to FIG. 4A and FIG. 4B, a pixel area PX may include an emission area EA and a transmission area TA.

The emission area EA may include a first sub-pixel SP1, a second sub-pixel SP2, a third sub-pixel SP3, and a fourth sub-pixel SP4. Embodiments are not limited thereto. As an example, the emission area EA may include less than 4 (e.g., 2, 3) sub-pixels or more than 4 (e.g., 5, 6, 8) sub-pixels.

As an example, the first sub-pixel SP1, the second sub-pixel SP2, the third sub-pixel SP3, and the fourth sub-pixel SP4 may emit light of different colors, respectively. For example, the first sub-pixel SP1, the second sub-pixel SP2, the third sub-pixel SP3, and the fourth sub-pixel SP4 may be a red sub-pixel which emits red light, a green sub-pixel which emits green light, a blue sub-pixel which emits blue light, and a white sub-pixel which emits white light. However, the present disclosure is not limited thereto. As an example, at least some of the first sub-pixel SP1, the second sub-pixel SP2, the third sub-pixel SP3, and the fourth sub-pixel SP4 may emit light of the same color.

As an example, a common organic layer may be provided in the first sub-pixel SP1, the second sub-pixel SP2, the third sub-pixel SP3, and the fourth sub-pixel SP4 so as to emit white light. Also, a color filter 170 for distinguishing colors may be provided.

Herein, the organic light emitting diode OLED may be disposed in the emission area EA on the substrate 110. Also, each of the first sub-pixel SP1, the second sub-pixel SP2, the third sub-pixel SP3, and the fourth sub-pixel SP4 may be partitioned by a bank layer 180.

A connection line 139 may be disposed in the transmission area TA on the substrate 110. The connection line 139 may extend from the emission area EA so as to be disposed in the transmission area TA. Also, as an example, the connection line 139 in the transmission area TA may be electrically connected to the second electrode of the organic light emitting diode OLED.

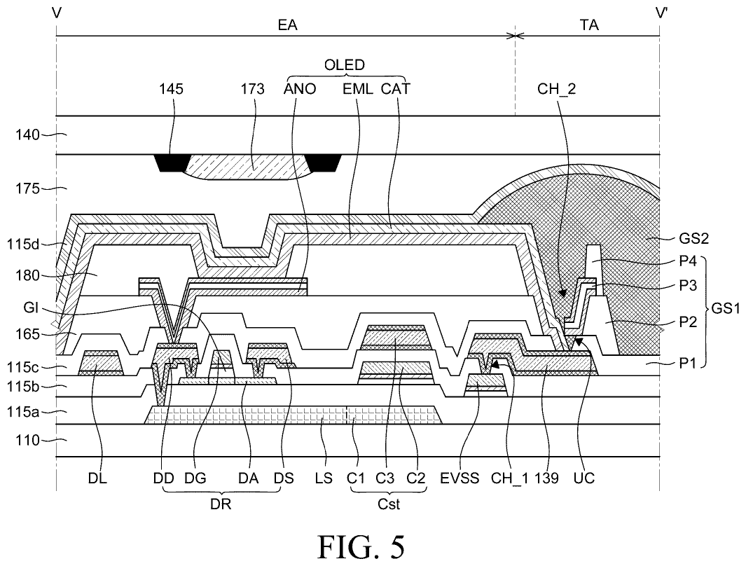

For example, the second electrode of the organic light emitting diode OLED may extend from the emission area EA to the transmission area TA. Also, the second electrode of the organic light emitting diode OLED may be electrically connected to an upper surface of the connection line 139 exposed under a second structure GS2. An electrical connection between the second electrode and the connection line 139 will be described in detail with reference to FIG. 5.

FIG. 4A illustrates that the connection line 139 extends to the transmission area TA from the third sub-pixel SP3 among the first to fourth sub-pixels SP1 to SP4. However, the present disclosure is not limited thereto. The connection line 139 may extend to the transmission area TA from one of the first to fourth sub-pixels SP1 to SP4. Also, as an example, the connection line 139 may extend to the transmission area TA from each of the first to fourth sub-pixels SP1 to SP4. As an example, the second electrode of the organic light emitting diode OLED in the first to fourth sub-pixels SP1 to SP4 may be commonly electrically connected to the connection line 139, without being limited thereto.

The connection line 139 will be described in detail with reference to FIG. 5.

The second structure GS2 may be disposed in the transmission area TA so as to cover the connection line 139. The second electrode of the organic light emitting diode OLED and the second power line EVSS may be electrically connected to each other under the second structure GS2.

The second structure GS2 will be described in detail with reference to FIG. 5.

Referring to FIG. 4B, as an example, the color filter 170 may be disposed in the emission area EA on an encapsulation substrate 140. As an example, the color filter 170 may be disposed in the emission area EA on an encapsulation substrate 140 so as to be enclosed by a black matrix 145. For example, a first color filter layer 171, a second color filter layer 172, and a third color filter layer 173 may be disposed in the first sub-pixel SP1, the second sub-pixel SP2, and the third sub-pixel SP3, respectively. Meanwhile, if the organic light emitting diode OLED emits white light and the fourth sub-pixel SP4 is a white sub-pixel, any color filter 170 may not be disposed in the fourth sub-pixel SP4. However, the present disclosure is not limited thereto. As an example, the black matrix 145 may be omitted depending on the design. As an example, the color filter 170 and the black matrix 145 may be omitted depending on the design.

Meanwhile, as an example, a reflective material is not disposed in the transmission area TA. However, a reflective material may be disposed depending on the design of the display device 100. In this case, as an example, a reduced or minimum amount of the reflective material may be disposed in the transmission area TA. Also, as an example, some of various insulating layers may be removed from the transmission area TA in order to secure transmittance, without being limited thereto. For example, an overcoating layer and the bank layer 180 may not be disposed in the transmission area TA. However, the present disclosure is not limited thereto.

FIG. 4A and FIG. 4B illustrate a transparent display device including the emission area EA composed of the first to fourth sub-pixels SP1 to SP4 and one transmission area TA. However, the present disclosure is not limited thereto.

Also, in the display device 100 according to an exemplary embodiment of the present disclosure, the first to fourth sub-pixels SP1 to SP4 may be defined by one gate line and four data lines each intersecting the one gate line. However, the present disclosure is not limited thereto. As an example, the first to fourth sub-pixels SP1 to SP4 may be defined by more than one gate lines and/or less than four data lines. As an example, at least some of the first to fourth sub-pixels SP1 to SP4 may share one data line and/or one gate line.

FIG. 5 is an example of a cross-sectional view taken along a line V-V′ of FIG. 4A.

Referring to FIG. 5, a light shielding layer LS may be disposed on the substrate 110.

As an example, the substrate 110 may be a rigid substrate or a flexible substrate. As an example, the substrate 110 may be a glass or plastic substrate, without being limited thereto. As an example, the substrate 110 may be a transparent substrate. If the substrate 110 is a plastic substrate, it may be made of a polyimide-based material or polycarbonate-based material and thus may have flexibility, without being limited thereto. In particular, polyimide is a material that can be processed at a high temperature and can be coated, and thus is widely used as a plastic substrate.

The light shielding layer LS may serve to block the introduction of external light and suppress the generation of a light current in a thin film transistor.

The light shielding layer LS may be made of an opaque conductive material. For example, the light shielding layer LS may be made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the light shielding layer LS may be configured by a single layer or a multi-layer made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the light shielding layer LS may be configured by a double layer of molybdenum/aluminum-neodymium or molybdenum/aluminum. As an example, the light shielding layer LS may be formed in the emission area EA but not in the transmission area TA.

The capacitor Cst may be disposed on the substrate 110. For example, the capacitor Cst may include a first capacitor electrode C1, a second capacitor electrode C2, and a third capacitor electrode C3, without being limited thereto.

As an example, the first capacitor electrode C1 of the capacitor Cst may be disposed on the same layer as the light shielding layer LS, without being limited thereto. The first capacitor electrode C1 may be formed by extending the light shielding layer LS, but is not limited thereto. The first capacitor electrode C1 may be provided separately from the light shielding layer LS on the same layer as the light shielding layer LS.

For example, the first capacitor electrode C1 be made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the first capacitor electrode C1 may be configured by a single layer or a multi-layer made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the first capacitor electrode C1 may be configured by a double layer of molybdenum/aluminum-neodymium or molybdenum/aluminum.

A buffer layer 115a may be disposed on the substrate 110 on which the light shielding layer LS is disposed. For example, the buffer layer 115a serves to protect thin film transistors formed in the subsequent process from impurities, such as alkali ions, discharged from the light shielding layer LS.

For example, the buffer layer 115a may be made of silicon oxide (SiOx), silicon nitride (SiNx), or a multi-layer thereof, without being limited thereto.

FIG. 5 illustrates the buffer layer 115a as a monolayer. However, the present disclosure is not limited thereto. The buffer layer 115a may be configured by a multi-layer.

The driving transistor DR may be disposed on the buffer layer 115a.

The driving transistor DR may include a semiconductor layer DA, a gate electrode DG, a source electrode DS, and a drain electrode DD.

The driving transistor DR may overlap the organic light emitting diode OLED, but is not limited thereto.

The semiconductor layer DA of the driving transistor DR may be disposed on the buffer layer 115a.

The semiconductor layer DA may be made of a silicon semiconductor or an oxide semiconductor. Also, the silicon semiconductor may include amorphous silicon or polycrystalline silicon. Embodiments are not limited thereto. As an example, the semiconductor layer DA may be made of other semiconductors such as compound semiconductor, organic semiconductor, etc.

Further, the semiconductor layer DA may include a drain region and a source region containing p-type or n-type impurities, and a channel region between the drain region and the source region.

Semiconductor layers of the sensing transistor ST and the switching transistor SW may be disposed on the same layer as the semiconductor layer DA of the driving transistor DR, or may be disposed on different layers.

For example, the semiconductor layers of the sensing transistor ST and the switching transistor SW may be made of a silicon semiconductor or an oxide semiconductor. Also, the silicon semiconductor may include amorphous silicon or polycrystalline silicon. However, the present disclosure is not limited thereto. As an example, the semiconductor layers of the sensing transistor ST and the switching transistor SW may be made of other semiconductors such as compound semiconductor, organic semiconductor, etc. As an example, the semiconductor layer DA, the semiconductor layers of the sensing transistor ST and the switching transistor SW may be made of the same material or different materials.

A gate insulating film GI may be disposed on the semiconductor layer DA.

For example, the gate insulating film GI may be made of silicon oxide (SiOx), silicon nitride (SiNx), or a multi-layer thereof, without being limited thereto.

FIG. 5 illustrates that the gate insulating film GI is patterned and disposed on a portion of the substrate 110. However, the present disclosure is not limited thereto. The gate insulating film GI may be disposed on the entire surface of the substrate 110.

Also, the gate electrode DG of the driving transistor DR may be disposed on the gate insulating film GI so as to correspond in position to the channel region of the semiconductor layer DA.

Although not illustrated in FIG. 5, gate electrodes of the sensing transistor and the switching transistor may be disposed on the same layer as the gate electrode DG of the driving transistor DR, without being limited thereto. As an example, gate electrodes of the driving transistor DR, the sensing transistor and the switching transistor may be disposed on different layers.

The gate electrode DG of the driving transistor DR may be made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the gate electrode DG of the driving transistor DR may be configured by a single layer or a multi-layer made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the gate electrode DG of the driving transistor DR may be configured by a double layer of molybdenum/aluminum-neodymium or molybdenum/aluminum as shown in FIG. 5.

The second capacitor electrode C2 of the capacitor Cst may be disposed on the same layer as the gate electrode DG of the driving transistor DR, or on a different layer. Herein, for example, the second capacitor electrode C2 may be made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the second capacitor electrode C2 may be configured by a single layer or a multi-layer made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the second capacitor electrode C2 may be configured by a double layer of molybdenum/aluminum-neodymium or molybdenum/aluminum.

The second power line EVSS may be disposed on the same layer as the gate electrode DG of the driving transistor DR or on a different layer.

For example, the second power line EVSS may be made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the second power line EVSS may be configured by a multi-layer made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the second power line EVSS may be configured by a double layer of molybdenum/aluminum-neodymium or molybdenum/aluminum as shown in FIG. 5.

An interlayer insulating film 115b may be disposed on the substrate 110 including the gate electrode DG of the driving transistor DR, the second capacitor electrode C2, and the second power line EVSS.

For example, the interlayer insulating film 115b may be made of silicon oxide (SiOx), silicon nitride (SiNx), or a multi-layer thereof, without being limited thereto.

The source electrode DS and the drain electrode DD of the driving transistor DR may be disposed on the interlayer insulating film 115b.

Also, the source electrodes and drain electrodes of the sensing transistor and the switching transistor may be disposed on the same layer as the source electrode DS and the drain electrode DD of the driving transistor DR, or on a different layer. However, the present disclosure is not limited thereto.

The source electrode DS and the drain electrode DD of the driving transistor DR, the source electrode and the drain electrode of the sensing transistor, and the source electrode and the drain electrode of the switching transistor may be made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the source electrode DS and the drain electrode DD of the driving transistor DR may be configured by a single layer or a multi-layer made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the source electrode DS and the drain electrode DD may be configured by a double layer of molybdenum/aluminum-neodymium or molybdenum/aluminum. As an example, the source electrode DS and the drain electrode DD of the driving transistor DR, the source electrode and the drain electrode of the sensing transistor, and the source electrode and the drain electrode of the switching transistor may be made of the same material or different materials.

The third capacitor electrode C3 of the capacitor Cst may be disposed on the same layer as the source electrode DS and the drain electrode DD of the driving transistor DR, or on a different layer. For example, the third capacitor electrode C3 may be made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the third capacitor electrode C3 may be configured by a single layer or a multi-layer made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the third capacitor electrode C3 may be configured by a double layer of molybdenum/aluminum-neodymium or molybdenum/aluminum.

Although not illustrated in the drawings, the data line DL, the first power line EVDD (see FIG. 3), and the sensing line VREF (see FIG. 3) may be disposed on the same layer as the gate electrode DG of the driving transistor DR, or on a different layer.

For example, the data line DL, the first power line EVDD (see FIG. 3), and the sensing line VREF (see FIG. 3) may be made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the data line DL, the first power line EVDD (see FIG. 3), and the sensing line VREF (see FIG. 3) may be configured by a single layer or a multi-layer made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the data line DL, the first power line EVDD (see FIG. 3), and the sensing line VREF (see FIG. 3) may be configured by a double layer of molybdenum/aluminum-neodymium or molybdenum/aluminum. As an example, the data line DL, the first power line EVDD (see FIG. 3), and the sensing line VREF (see FIG. 3) may be made of the same material or different materials.

As an example, the connection line 139 may be disposed on the same layer as the source electrode DS and the drain electrode DD of the driving transistor DR and the third capacitor electrode C3 of the capacitor Cst, or on a different layer.

For example, the connection line 139 may be disposed on the same layer as the gate electrode DG of the driving transistor DR, without being limited thereto. The connection line 139 may be electrically connected to the second power line EVSS through a first contact hole CH_1 in the emission area EA.

Also, for example, the connection line 139 may be connected to a second electrode CAT in the transmission area TA. Therefore, the connection line 139 may serve to reduce a resistance while applying a low-potential voltage to the second electrode CAT of the organic light emitting diode OLED.

For example, the connection line 139 may be made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the connection line 139 may be configured by a single layer or a multi-layer made of one or more selected from the group consisting of molybdenum (Mo), aluminum (Al), chromium (Cr), gold (Au), titanium (Ti), nickel (Ni), neodymium (Nd), and copper (Cu), or an alloy thereof. For example, the connection line 139 may be configured by a double layer of molybdenum/aluminum-neodymium or molybdenum/aluminum.

A passivation film 115c may be disposed on the substrate 110 including the driving transistor DR and the capacitor Cst. For example, the passivation film 115c is an insulating film serving to protect the underlying components, and may be made of silicon oxide (SiOx), silicon nitride (SiNx), or a multi-layer thereof, without being limited thereto.

An overcoating layer 165 may be disposed on the passivation film 115c.

The overcoating layer 165 may be a planarization film for reducing a step difference on the underlying structure, and may be made of an organic material, such as polyimide, benzocyclobutene series resin, acrylate, etc.

For example, the overcoating layer 165 may be formed through a spin on glass (SOG) method for coating the organic material in a liquid state and then curing the organic material.

The organic light emitting diode OLED may be disposed on the overcoating layer 165.

The organic light emitting diode OLED may include a first electrode ANO, an organic layer EML, and the second electrode CAT.

More specifically, the first electrode ANO may be disposed on the overcoating layer 165. Herein, the first electrode ANO serves as a pixel electrode and may be connected to the drain electrode DD of the driving transistor DR.

As an example, the first electrode ANO may be made of a transparent conductive material, such as indium tin oxide (ITO), indium zinc oxide (IZO), or zinc oxide (ZnO). As an example, the first electrode ANO may be made of a semi-transparent conductive material or an opaque conductive material. For example, the display device 100 according to an exemplary embodiment of the present disclosure may have a top emission structure, and in this case, the first electrode ANO may be configured by a reflective electrode. Therefore, the first electrode ANO may further include a reflective layer. Herein, for example, the reflective layer may be made of aluminum (Al), copper (Cu), silver (Ag), nickel (Ni), or an alloy thereof, without being limited thereto. Desirably, the reflective layer may be made of an Ag/Pd/Cu (APC) alloy.

Further, the bank layer 180 defining the first to fourth sub-pixels SP1 to SP4 may be disposed on the substrate 110 including the first electrode ANO. For example, the bank layer 180 may be made of an organic material, such as polyimide, benzocyclobutene series resin, acrylate, etc.

Although not illustrated in FIG. 5, a spacer may be further disposed on the bank layer 180. The spacer may serve to suppress damage to the organic light emitting diode OLED when a fine metal mask (FMM) used for forming the organic layer EML of the organic light emitting diode OLED is brought into direct contact with the bank layer 180 or the second electrode CAT. The spacer may be made of the same material as the bank layer 180, or may be made of a different material from the bank layer 180, but is not limited thereto. Also, the spacer and the bank layer 180 may be integrally formed. Since the spacer is disposed on the bank layer 180, the second electrode CAT and the organic layer EML may be disposed to cover the spacer and the bank layer 180.

In the display device 100 according to an exemplary embodiment of the present disclosure, a first structure GS1 may be disposed on an end of the connection line 139.

The first structure GS1 may be disposed in the transmission area TA, and may be disposed to overlap a part of the connection line 139.

The first structure GS1 may be disposed in an island shape. For example, the first structure GS1 may be formed into an island shape during a process of forming a second contact hole CH_2 in the first electrode ANO, the bank layer 180, the overcoating layer 165, and the passivation layer 115c. The second contact hole CH_2 may be referred to as a cathode contact hole. The first structure GS1 formed into an island shape may include a first pattern P1 located on the same layer as the passivation layer 115c, and a second pattern P2 located on the same layer as the overcoating layer 165. The first structure GS1 may also include a third pattern P3 located on the same layer as the first electrode ANO, and a fourth pattern P4 located on the same layer as the bank layer 180.

The first structure GS1 patterned into an island shape may have an undercut (UC) formed by etching side surfaces of the first pattern P1 and the second pattern P2 under the third pattern P3 so as to be further inward than the third pattern P3.

Meanwhile, a part of the upper surface of the connection line 139 may be exposed under the first structure GS1 by the undercut of the first structure GS1.

The organic layer EML in contact with the first electrode ANO may be disposed on the substrate 110. Herein, the organic layer EML includes an emission layer in which electrons and holes are recombined to emit light. The organic layer EML may also include a hole injection layer and/or a hole transport layer between the emission layer and the first electrode ANO. The organic layer EML may further include an electron transport layer and/or an electron injection layer on the emission layer. As an example, at least one of the hole injection layer, the hole transport layer, the electron transport layer and the electron injection layer may be omitted depending on the design.

The organic layer EML may be disposed in the first to fourth sub-pixels SP1 to SP4, and may be a common organic layer which emits white light. However, the present disclosure is not limited thereto. A red organic layer, a green organic layer, a blue organic layer, and a white organic layer may be disposed in the first to fourth sub-pixels SP1 to SP4, respectively.

The organic layer EML may extend to the neighboring sub-pixels SP1 to SP4 and the transmission area TA, but is not limited thereto. As an example, the organic layer EML may be disposed only on the first electrode ANO exposed by the bank layer 180. As an example, the organic layer EML may be disposed in only a portion of the transmission area TA.

The second electrode CAT may be disposed on the organic layer EML. The second electrode CAT serves as a cathode, and may be disposed on the entire surface of the display area. The second electrode CAT may be made of, for example, magnesium (Mg), calcium (Ca), aluminum (Al), silver (Ag), which have a low work function, or an alloy thereof. As an example, the second electrode CAT may be a transmission electrode and may be formed thin enough to transmit light.

Meanwhile, as an example, the organic layer EML and the second electrode CAT may extend to the transmission area TA, for example, to below the first structure GS1. The organic layer EML and the second electrode CAT may be disconnected in the undercut of the first structure GS1. The organic layer EML and the second electrode CAT disconnected by the undercut UC may be laminated on the first structure GS1, which is not illustrated in the drawings. However, the present disclosure is not limited thereto. For example, the second electrode CAT may be electrically connected to the exposed part of the upper surface of the connection line 139 through the second contact hole CH_2 under the first structure GS1 having the undercut UC. Also, the second electrode CAT may be electrically connected to the second power line EVSS through the connection line 139.

The second structure GS2 may be disposed to cover the first structure GS1.

The second structure GS2 may be disposed in the transmission area TA, and may have a hemispherical shape. FIG. 5 illustrates that the second structure GS2 has a hemispherical shape. However, the second structure GS2 may have a semi-elliptical shape, or may have various other shapes. As an example, the second structure GS2 may be disposed in a portion of the transmission area TA. As an example, the second structure GS2 may be disposed in a portion of the emission area EA. As an example, the second structure GS2 may be disposed to overlap a boundary between the emission area EA and the transmission area TA. As an example, the second structure GS2 may have a curved shape. As an example, the second structure GS2 may cover a top surface of the first structure GS1.

For example, the second structure GS2 may be disposed in the transmission area TA while covering at least a part of an end of the bank layer 180 disposed in the emission area EA. For example, the second structure GS2 may entirely cover the first structure GS1. For example, the second structure GS2 may be disposed to cover the first structure GS1 while filling the second contact hole CH_2 formed in the overcoating layer 165, the passivation layer 115c, the first electrode ANO, and the bank layer 180.

As an example, the second structure GS2 may be made of a transparent material. As an example, the second structure GS2 may be made of a material having a transmittance of 95% or more. The second structure GS2 may be made of curable resin. For example, the second structure GS2 may be made of thermosetting resin or photocurable resin having a viscosity of 50,000 centipoises (cPs) or more, e.g., 100,000 cPs or more. For example, the second structure GS2 may be made of an epoxy-based, urethane-based, silicone-based or acryl-based material, without being limited thereto.

A protection layer 115d may be disposed on the second electrode CAT and the second structure GS2.

The protection layer 115d may be an inorganic layer. In this case, the protection layer 115d may be made of silicon oxide (SiOx), silicon nitride (SiNx), or a multi-layer thereof, without being limited thereto. As an example, the protection layer 115d may be a transparent layer.

The protection layer 115d may extend to the transmission area TA. For example, the protection layer 115d may extend to the transmission area TA so as to be disposed on the second structure GS2. The second structure GS2 may be disposed to fill the second contact hole CH_2 and thus may be in contact with a part of the second electrode CAT in the transmission area TA. For example, the second structure GS2 may be disposed between the second electrode CAT and the protection layer 115d in the transmission area TA.

For example, an upper surface of the protection layer 115d may have a height equal to or greater than the organic light emitting diode OLED and equal to or smaller than a lower surface of the encapsulation substrate 140, but is not limited thereto. The upper surface of the protection layer 115d may have a height equal to or greater than the organic light emitting diode OLED and smaller than the lower surface of the encapsulation substrate 140. For example, when the upper surface of the protection layer 115d has a height equal to or greater than the organic light emitting diode OLED and equal to the lower surface of the encapsulation substrate 140, at least a part of the protection layer 115d on the second structure GS2 may be in contact with the encapsulation substrate 140. For example, when the upper surface of the protection layer 115d has a height equal to or greater than the organic light emitting diode OLED and smaller than the lower surface of the encapsulation substrate 140, the protection layer 115d on the second structure GS2 may be spaced apart from the encapsulation substrate 140. As an example, the protection layer 115d may be conformally formed on the second structure GS2 in the transmission area TA. As an example, an upper surface of the protection layer 115d may have a curved shape in the transmission area TA. As an example, an upper surface of the protection layer 115d may have a height equal to or greater than an upper surface of the second electrode CAT of the organic light emitting diode OLED. As an example, an upper surface of the protection layer 115d may have a height equal to or greater than an upper surface of the second electrode CAT on the bank layer 180. As an example, an upper surface of the protection layer 115d may be higher than an upper surface of the second electrode CAT on the bank layer 180. As an example, when at least a part of the protection layer 115d on the second structure GS2 is in contact with the encapsulation substrate 140, the color filter 170 or the black matrix 145 is still spaced apart from the organic light emitting diode OLED (e.g., the upper surface of the second electrode CAT on the bank layer 180).

Although not illustrated in the drawings, a capping layer may further be disposed on the organic light emitting diode OLED. The capping layer may be made of a material having a high refractive index and a high light absorption rate to reduce diffused reflection of external light. As an example, the capping layer may be omitted depending on the design.

An adhesive layer 175 and the encapsulation substrate 140 may be disposed on the protection layer 115d.

The adhesive layer 175 may be made of curable resin, without being limited thereto. For example, the curable resin may be thermosetting resin or photocurable resin having a viscosity of 50 cPs or more.

Although not illustrated in the drawings, a dam may be disposed in an outer portion corresponding to the non-display area NA of the substrate 110 so as to enclose the adhesive layer 175. The dam may serve to enhance the adhesive strength between the substrate 110 and the encapsulation substrate 140 in the non-display area NA of the display device 100 and reduce or minimize moisture permeation.

Also, the black matrix 145 may be disposed on one surface of the encapsulation substrate 140 facing the substrate 110. Herein, the one surface of the encapsulation substrate 140 facing the substrate 110 will be referred to as an upper surface, for the convenience of description.

For example, the black matrixes 145 of the neighboring sub-pixels SP1 to SP4 may be spaced apart from each other and thus may have openings.

The color filter 170 may be disposed on the openings. The color filter 170 serves as a light conversion member to convert light emitted from the organic light emitting diode OLED into light of various colors. For example, the color filter 170 may be disposed in the first sub-pixel SP1, the second sub-pixel SP2, and the third sub-pixel SP3 in the emission area EA. Also, the color filter 170 may be disposed to overlap a part of an upper surface of the black matrix 145. For example, the color filter 170 may include the first color filter layer 171 (see FIG. 4B), the second color filter layer 172 (see FIG. 4B), and the third color filter 173 (see FIG. 4B). For example, the color filter 170 may be disposed in the emission area EA, particularly in an area where the first electrode ANO, the organic layer EML, and the second electrode CAT overlap one another. Therefore, the color filter 170 does not overlap the first structure GS1 and the second structure GS2 disposed in the transmission area TA.

The first color filter layer 171 may be disposed in the first sub-pixel SP1. For example, the first color filter layer 171 may be a red color filter layer. Thus, light emitted from the organic light emitting diode OLED may be converted into red light through the first color filter layer 171 disposed in the first sub-pixel SP1.

The second color filter layer 172 may be disposed in the second sub-pixel SP2. For example, the second color filter layer 172 may be a green color filter layer. Thus, light emitted from the organic light emitting diode OLED may be converted into green light through the second color filter layer 172 disposed in the second sub-pixel SP2.

The third color filter layer 173 may be disposed in the third sub-pixel SP3. For example, the third color filter layer 173 may be a blue color filter layer. Thus, light emitted from the organic light emitting diode OLED may be converted into blue light through the third color filter layer 173 disposed in the third sub-pixel SP3.

Therefore, in the display device 100 according to an exemplary embodiment of the present disclosure, the first structure GS1 is provided on an end of the connection line 139. Also, the second structure GS2 is provided on the first structure GS1 so as to overlap the connection line 139 and the first structure GS1. Thus, the undercut UC of the first structure GS1 may be covered by the second structure GS2. For example, the second structure GS2 may also be disposed under the undercut UC of the first structure GS1. Therefore, the second structure GS2 may reinforce the undercut UC of the first structure GS1 and thus suppress the occurrence of a seam under the first structure GS1. Accordingly, it is possible to improve the reliability of the display device 100 by suppressing the permeation of foreign matter, such as moisture, gas, or oxygen, from the outside into the display device 100 through the undercut UC of the first structure GS1.

Also, the second structure GS2 is provided on the first structure GS1. Herein, the second structure GS2 has a height equal to or greater than the organic light emitting diode OLED and smaller than the lower surface of the encapsulation substrate 140. Thus, a uniform cell gap can be maintained during a process of bonding the substrate 110 to the encapsulation substrate 140. Therefore, it is possible to suppress a pressing dark spot caused by foreign matter generated inside the display device 100.

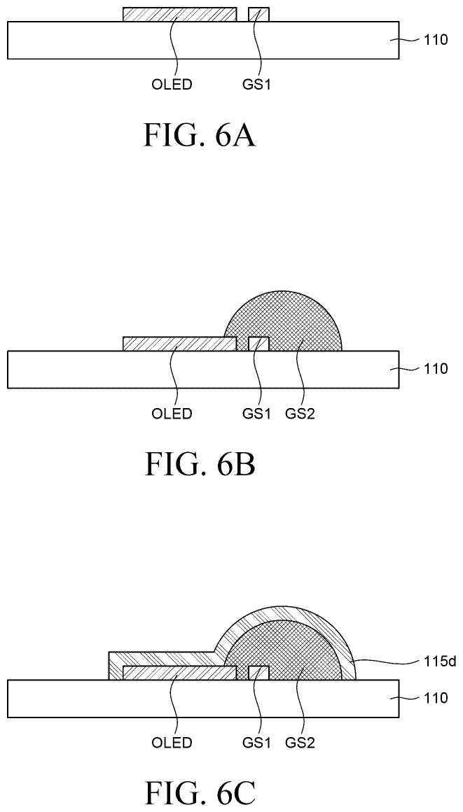

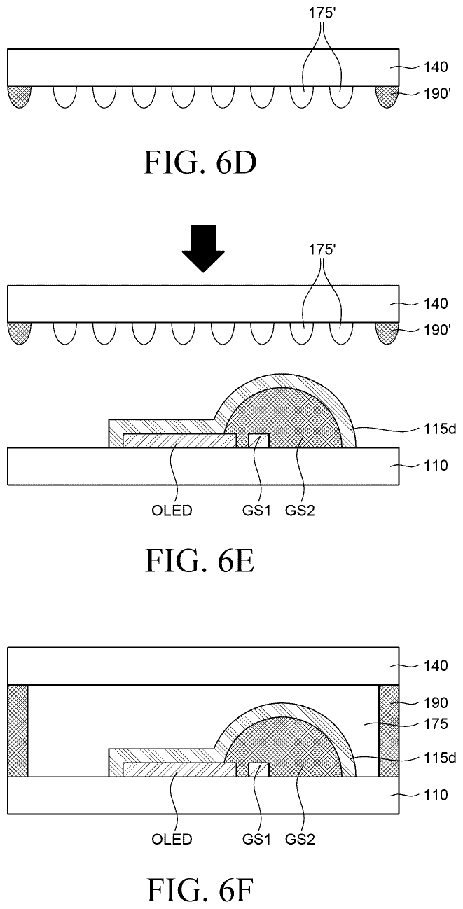

FIG. 6A through FIG. 6F are schematic diagrams illustrating a method of manufacturing a display device according to an exemplary embodiment of the present disclosure. The method of manufacturing a display device shown in FIG. 6A through FIG. 6F is performed to manufacture the display device illustrated in FIG. 1 through FIG. 5. The same reference numeral will be used for the same component. Hereinafter, descriptions of the same reference numerals may refer to FIG. 1 through FIG. 5. FIG. 6A through FIG. 6F illustrate that a pixel including the organic light emitting diode OLED in an emission area and the second structure GS2 in a transmission area is formed on the substrate 110, for the convenience of description. However, a plurality of pixels may be formed on the substrate 110.

First, as shown in FIG. 6A, the substrate 110 is prepared. Herein, the organic light emitting diode OLED corresponding to the emission area EA of FIG. 4A and FIG. 5 and the first structure GS1 spaced apart from the organic light emitting diode OLED and corresponding to the transmission area TA are disposed on the substrate 110. FIG. 6A illustrates the organic light emitting diode OLED, for the convenience of description. However, all the components disposed under the organic light emitting diode OLED of FIG. 5 may be included in the organic light emitting diode OLED. Also, FIG. 6A schematically illustrates the shape of the first structure GS1, for the convenience of description. The first structure GS1 may have an undercut shape as shown in FIG. 5.

Then, as shown in FIG. 6B, the second structure GS2 is provided to overlap a part of one end of the organic light emitting diode OLED and cover the first structure GS1. For example, curable resin having a viscosity of 50,000 cPs or more is coated on a portion corresponding to the transmission area of the substrate 110, followed by UV curing to form the second structure GS2.

Thereafter, as shown in FIG. 6C, the protection layer 115d is provided to cover the organic light emitting diode OLED and the second structure GS2.

Meanwhile, as shown in FIG. 6D, the encapsulation substrate 140 is prepared separately from the substrate 110 on which the organic light emitting diode OLED and the second structure GS2 are provided. A dam composition 190′ is coated on one surface of the encapsulation substrate 140 facing the substrate 110 so as to correspond to both ends of the substrate 110. Also, an adhesive layer composition 175′ is coated inside the dam composition 190′. As an example, the adhesive layer composition 175′ is coated between the dam composition 190′ at both ends of the substrate 110. As an example, the adhesive layer composition 175′ is coated at an inner side of the dam composition 190′ at both ends of the substrate 110. The dam composition 190′ may be made of curable resin. For example, the dam composition 190′ may be made of thermosetting resin or photocurable resin having a viscosity of 50,000 cPs or more, e.g., 100,000 cPs or more. For example, the dam composition 190′ may further contain a moisture adsorption material in the curable resin, but is not limited thereto. Although not illustrated in the drawings, the black matrix 145 and the color filter 170 may be disposed on the one surface of the encapsulation substrate 140 facing the substrate 110 at an inner side of the dam composition 190′.

Then, as shown in FIG. 6E, the substrate 110 on which the organic light emitting diode OLED and the second structure GS2 are provided is bonded to the encapsulation substrate 140 on which the dam composition 190′ and the adhesive layer composition 175′ are coated. Thereafter, the dam composition 190′ and the adhesive layer composition 175′ are cured to form a dam 195 and the adhesive layer 175.

It is important to maintain a uniform cell gap during a process of bonding the substrate 110 to the encapsulation substrate 140. As a distance from a dam increases, a lot of pressing dark spots occur due to sagging of the encapsulation substrate 140. That is, if there is no structure for maintaining a cell gap, a pressing dark spot may be caused by a small cell gap. Also, a pressing dark spot may be caused by foreign matter generated inside the display panel during the bonding process.

Thus, in the display device 100 according to an exemplary embodiment of the present disclosure, the second structure GS2 is provided in the transmission area TA. Therefore, a uniform cell gap can be maintained by the second structure GS2, and a pressing dark spot caused by foreign matter generated inside the display device 100 can be suppressed. As an example, the second structure GS2 in different transmission areas TA has substantially the same height. As an example, the protection layer 115d on the second structure GS2 in at least one transmission areas TA may be in contact with the one surface of the encapsulation substrate 140 facing the substrate 110.

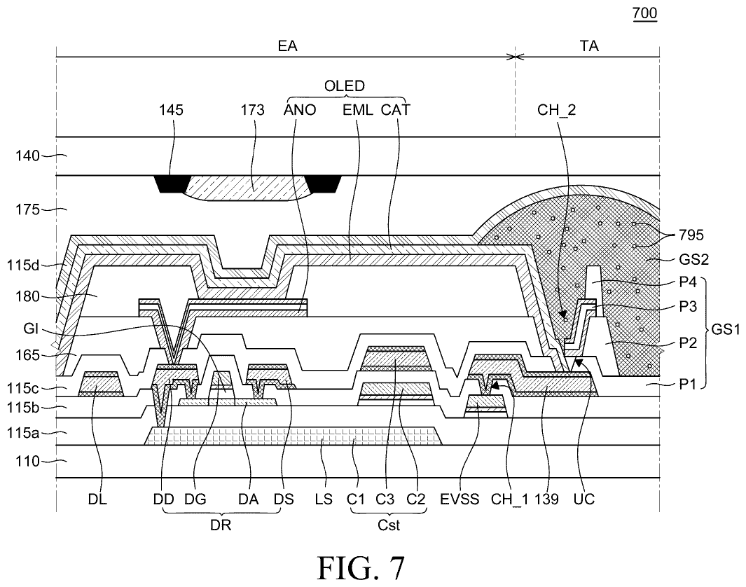

FIG. 7 is a cross-sectional view of a display device according to another exemplary embodiment of the present disclosure. A display device 700 of FIG. 7 is substantially the same as the display device 100 of FIG. 1 through FIG. 6 except the second structure GS2. Therefore, redundant description thereof will be omitted or briefly given. The same reference numeral will be used for the same component. Hereinafter, descriptions of the same reference numerals may refer to FIG. 1 through FIG. 6.

Referring to FIG. 7, the display device 700 according to another exemplary embodiment of the present disclosure may further include an adsorption material 795 dispersed in the second structure GS2.

The adsorption material 795 may include, for example, a getter material which can adsorb moisture, oxygen, or hydrogen. For example, the getter material may include nickel (Ni), cerium (Ce), or a combination thereof, but is not limited thereto.

The size of the adsorption material 795 is not limited as long as it does not affect the transmittance of the transmission area TA. For example, the adsorption material 795 may have a particle size of less than 100 nm.

In the display device 700 according to another exemplary embodiment of the present disclosure, the second structure GS2 contains the adsorption material 795. Thus, when moisture permeates into the second structure GS2, the getter material adsorbs moisture and suppresses the diffusion of moisture, oxygen, or hydrogen. Therefore, it is possible to improve the reliability of the display device 700.

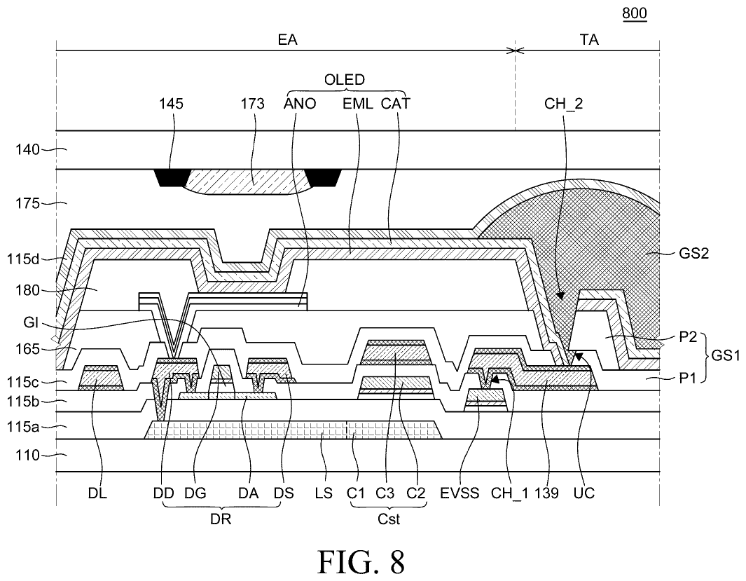

FIG. 8 is a cross-sectional view of a display device according to yet another exemplary embodiment of the present disclosure. A display device 800 of FIG. 8 is substantially the same as the display device 100 of FIG. 1 through FIG. 6 except the first structure GS1. Therefore, redundant description thereof will be omitted. The same reference numeral will be used for the same component. Hereinafter, descriptions of the same reference numerals may refer to FIG. 1 through FIG. 6.

Referring to FIG. 8, in the display device 800 according to yet another exemplary embodiment of the present disclosure, the first structure GS1 may be disposed on an end of the connection line 139.

The first structure GS1 may be disposed in the transmission area TA, and may be disposed to overlap a part of the connection line 139.

The first structure GS1 may be disposed in an island shape. For example, the first structure GS1 may be formed into an island shape during a process of forming the second contact hole CH_2 in the bank layer 180, the overcoating layer 165, and the passivation layer 115c. The second contact hole CH_2 may be referred to as a cathode contact hole.

The first structure GS1 formed into an island shape may include the first pattern P1 located on the same layer as the passivation layer 115c, and the second pattern P2 located on the same layer as the overcoating layer 165.

The undercut UC may be provided under the first structure GS1 patterned into an island shape. For example, the undercut UC may be formed by etching a side surface of the first pattern P1 of the first structure GS1 to be further inward than a side surface of the second pattern P2.

Meanwhile, a part of the upper surface of the connection line 139 may be exposed by the second contact hole CH_2.

The second contact hole CH_2 may expose a part of the upper surface of a cathode connection line 139b under the first structure GS1. Also, a part of the upper surface of the connection line 139 may be exposed adjacent to the first structure GS1.

The organic layer EML and the second electrode CAT extending from the emission area EA may be disposed on the first structure GS1. For example, the organic layer EML and the second electrode CAT may extend from the emission area EA to the transmission area TA and may be disconnected from the organic layer EML and the second electrode CAT on the first structure GS1 by the undercut UC. For example, the second electrode CAT may extend to the transmission area TA and may be electrically connected to the upper surface of the connection line 139 exposed by the second contact hole CH_2. For example, a part of the organic layer EML and the second electrode CAT disconnected by the undercut UC may be laminated in an island shape on the first structure GS1.

The second structure GS2 may be disposed to cover the first structure GS1.

The second structure GS2 may be disposed in the transmission area TA, and may have a hemispherical shape. FIG. 8 illustrates that the second structure GS2 has a hemispherical shape. However, the second structure GS2 may have a semi-elliptical shape, or may have various other shapes.

For example, the second structure GS2 may be disposed in the transmission area TA while covering at least a part of an end of the bank layer 180 disposed in the emission area EA and thus may entirely cover the first structure GS1. For example, the second structure GS2 may be disposed to cover the first structure GS1 while filling the second contact hole CH_2 formed in the bank layer 180, the overcoating layer 165, and the passivation layer 115c. For example, the second structure GS2 may be disposed to be in contact with the first pattern P1 and the second pattern P2 the first structure GS1 formed into an island shape through the second contact hole CH_2.

The second structure GS2 may be made of a transparent material. As an example, the second structure GS2 may be made of a material having a transmittance of 95% or more. The second structure GS2 may be made of curable resin. For example, the second structure GS2 may be made of thermosetting resin or photocurable resin having a viscosity of 50,000 cPs or more, e.g., 100,000 cPs or more. For example, the second structure GS2 may be made of an epoxy-based, urethane-based, silicone-based or acryl-based material, without being limited thereto.

The protection layer 115d may be disposed on the second electrode CAT and the second structure GS2. Meanwhile, the second structure GS2 may be disposed to fill the second contact hole CH_2 and thus may be in contact with a part of the second electrode CAT in the transmission area TA. For example, the second structure GS2 may be disposed between the second electrode CAT and the protection layer 115d in the transmission area TA.

The protection layer 115d may be an inorganic layer. In this case, the protection layer 115d may be made of silicon oxide (SiOx), silicon nitride (SiNx), or a multi-layer thereof, without being limited thereto.

The protection layer 115d may extend to the transmission area TA. For example, the protection layer 115d may extend to the transmission area TA so as to be disposed on the second structure GS2. The second structure GS2 may be disposed to fill the second contact hole CH_2 and thus may be in contact with a part of the second electrode CAT in the transmission area TA. For example, the second structure GS2 may be disposed between the second electrode CAT and the protection layer 115d in the transmission area TA.

As described above, in the display device 800 according to yet another exemplary embodiment of the present disclosure, the first structure GS1 is provided on an end of the connection line 139. Also, the second structure GS2 is provided on the first structure GS1 so as to overlap the connection line 139 and the first structure GS1. Thus, the undercut UC of the first structure GS1 is covered by the second structure GS2. For example, the second structure GS2 may also be disposed under the undercut UC of the first structure GS1. Therefore, the second structure GS2 may reinforce the undercut UC of the first structure GS1 and thus suppress the occurrence of a seam under the first structure GS1. Accordingly, it is possible to improve the reliability of the display device 800 by suppressing the permeation of foreign matter, such as moisture, gas, or oxygen, from the outside into the display device 800 through the undercut UC of the first structure GS1.

Also, the second structure GS2 is provided on the first structure GS1. Herein, the second structure GS2 has a height equal to or greater than the organic light emitting diode OLED and smaller than the lower surface of the encapsulation substrate 140. Thus, a uniform cell gap can be maintained during a process of bonding the substrate 110 to the encapsulation substrate 140. Therefore, it is possible to suppress a pressing dark spot caused by foreign matter generated inside the display device 800.

The exemplary embodiments of the present disclosure can also be described as follows:

According to an aspect of the present disclosure, a display device may comprise a substrate, a plurality of pixels, each of the plurality of pixels including an emission area and a transmission area, a first structure disposed in the transmission area on the substrate and having an undercut shape, an encapsulation substrate disposed on the substrate, and a second structure disposed between the substrate and the encapsulation substrate so as to cover the first structure.

The display device may further comprise a thin film transistor disposed in the emission area, an inorganic insulating layer covering the thin film transistor, an overcoating layer disposed on the inorganic insulating layer in the emission area, an organic light emitting diode disposed on the overcoating layer in the emission area, and a bank layer covering at least a part of a first electrode of the organic light emitting diode and defining a light emission area, the first structure includes a first pattern located on the same layer as the inorganic insulating layer, a second pattern disposed on the first pattern and located on the same layer as the overcoating layer, a third pattern disposed on the second pattern and located on the same layer as the first electrode of the organic light emitting diode, and a fourth pattern disposed on the third pattern and located on the same layer as the bank layer.

The display device may further comprise a power line disposed under the first structure, a second electrode of the organic light emitting diode is electrically connected to the power line under the first structure.

The display device may further comprise a connection line electrically connected to the power line through a first contact hole in the emission area.

The second structure has a hemispherical shape or a semi-elliptical shape.

The second structure contains a curable material having a viscosity of 50,000 cPs or more.

the second structure further contains an adsorption material having a particle size of less than 100 nm and greater than 0 nm.

The display device may further comprise a dam located on both ends of the substrate and the encapsulation substrate, the dam contains a curable material having a viscosity of 50,000 cPs or more.

The second structure has a height equal to or greater than the organic light emitting diode and smaller (or less) than a lower surface of the encapsulation substrate. For example, an upper surface of the second structure is at a same level as or higher than an upper surface of the organic light emitting diode and is below a lower surface of the encapsulation substrate.

The display device may further comprise a protection layer covering the organic light emitting diode and the second structure.

An upper surface of the protection layer has a height equal to or greater than the organic light emitting diode and equal to or smaller (or less) than a lower surface of the encapsulation substrate. For example, an upper surface of the protection layer is at a same level as or higher than an upper surface of the organic light emitting diode and is at a same level as or lower than a lower surface of the encapsulation substrate.

The protection layer on the second structure is spaced apart from the encapsulation substrate.

An adhesive layer is disposed between the protection layer on the second structure and the encapsulation substrate.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate;
a plurality of pixels, each of the plurality of pixels including an emission area and a transmission area;
a first structure disposed in the transmission area on the substrate and having an undercut portion exposing a portion of a connection line electrically connected to a power line;
an encapsulation substrate disposed on the substrate; and
a second structure disposed between the substrate and the encapsulation substrate so as to cover the first structure.

2. The display device according to claim 1, further comprising:
a thin film transistor disposed in the emission area;
an inorganic insulating layer covering the thin film transistor;
an overcoating layer disposed on the inorganic insulating layer in the emission area;
an organic light emitting diode disposed on the overcoating layer in the emission area; and
a bank layer covering at least a part of a first electrode of the organic light emitting diode and defining a light emission area.

3. The display device according to claim 2,
wherein the first structure includes a first pattern located on a same layer as the inorganic insulating layer, a second pattern disposed on the first pattern and located on a same layer as the overcoating layer, a third pattern disposed on the second pattern and located on a same layer as the first electrode of the organic light emitting diode, and a fourth pattern disposed on the third pattern and located on a same layer as the bank layer.

4. The display device according to claim 3, wherein side surfaces of the first pattern and the second pattern under the third pattern are located to be further inward than the third pattern, to form the undercut portion.

5. The display device according to claim 1,
wherein a second electrode of the organic light emitting diode extends to be connected to the exposed portion of the connection line at the undercut portion.

6. The display device according to claim 5,
wherein the second electrode and an organic layer of the organic light emitting diode extend to the transmission area to below the first structure, and are disconnected at the undercut portion.

7. The display device according to claim 1,
wherein the connection line is electrically connected to the power line through a first contact hole in the emission area.

8. The display device according to claim 1,
wherein second structure fill the undercut portion to be in contact with a side surface of the undercut portion.

9. The display device according to claim 1,
wherein second structure cover a part of a bank layer for defining a light emission area in the emission area.

10. The display device according to claim 1, wherein the second structure has a hemispherical shape or a semi-elliptical shape.

11. The display device according to claim 1, wherein the second structure contains a curable material having a viscosity of 50,000 cPs or more.

12. The display device according to claim 1, wherein the second structure further contains an adsorption material.

13. The display device according to claim 2, further comprising:
a dam located on both ends of the substrate and the encapsulation substrate,
wherein the dam contains a curable material having a viscosity of 50,000 cPs or more.

14. The display device according to claim 13, wherein the second structure has a height equal to or higher than the organic light emitting diode and lower than a lower surface of the encapsulation substrate.

15. The display device according to claim 2, further comprising:
a protection layer covering the organic light emitting diode and the second structure.

16. The display device according to claim 15, wherein an upper surface of the protection layer has a height equal to or higher than the organic light emitting diode and equal to or lower than a lower surface of the encapsulation substrate.

17. The display device according to claim 16, wherein the protection layer on the second structure is in contact with or spaced apart from the encapsulation substrate.

18. The display device according to claim 16, wherein an adhesive layer is disposed between the protection layer on the second structure and the encapsulation substrate.

19. The display device according to claim 16, further comprising a color filter disposed in the emission area on the encapsulation substrate,
wherein when the protection layer on the second structure is in contact with the encapsulation substrate, the color filter is spaced apart from the organic light emitting diode.
